(19) United States
(12) Patent Application Publication
(10) Pub. No.: US 2025/0380561 A1
(43) Pub. Date: Dec. 11, 2025

(54) ORGANIC TRANSPARENT CONDUCTIVE ELECTRODE FOR REPLACEMENT OF THE ITO ELECTRODE IN INDOOR-COMPATIBLE ORGANIC PHOTOVOLTAIC MODULES

(71) Applicant: DRACULA TECHNOLOGIES, VALENCE (FR)

(72) Inventors: Donia FREDJ, Marseille (FR); Sadok BEN DKHIL, VALENCE (FR); Brice CRUCHON, GUILHERAND GRANGES (FR)

(21) Appl. No.: 18/878,552

(22) PCT Filed: Sep. 19, 2023
(86) PCT No.: PCT/FR2023/051423

§ 371 Date: Dec. 23, 2024

(30) Foreign Application Priority Data
Sep. 19, 2022 (FR) 2209450
Jan. 5, 2023 (FR) 2300126

(51) Int. Cl. H10K 30/82; H10K 30/40

(52) U.S. Cl. CPC H10K 30/82; H10K 30/40

(57) ABSTRACT

The present invention relates to a photovoltaic module comprising, amongst others, a lower electrode consisting of two layers: a first layer comprising a polymer blend of poly(3,4-ethylenedioxythiophene) and sodium poly(styrene-sulfonate) covering the support and having an average thickness between 50 nm and 150 nm and an organic fibrous structure, and a second layer based on an organic polymer or molecule covering said first layer, the lower electrode having a lower surface in contact with the support and an upper surface, and an upper electrode comprising a polymer blend of poly(3,4-ethylenedioxythiophene) and sodium poly(styrene-sulfonate) covering said photovoltaic active layer, said electrode being continuous, having an average thickness of between 100 nm and 400 nm and an organic fibrous structure.

### CROSS-REFERENCE TO RELATED APPLICATIONS

The present application is a filing under 35 U.S.C. 371 as the National Stage of International Application No. PCT/FR2023/051423, filed Sep. 19, 2023, entitled “ORGANIC TRANSPARENT CONDUCTIVE ELECTRODE FOR REPLACEMENT OF THE ITO ELECTRODE IN INDOOR-COMPATIBLE ORGANIC PHOTOVOLTAIC MODULES,” which claims priority to France Application No. 2209450 filed with the Intellectual Property Office of France on Sep. 19, 2022 and claims priority to France Application No. 2300126 filed with the Intellectual Property Office of France on Jan. 5, 2023, all of which are incorporated herein by reference in their entirety for all purposes.

### TECHNICAL FIELD OF THE INVENTION

The invention relates in general to photovoltaic modules, and in particular to photovoltaic modules comprising several Organic Photovoltaic Cells (OPC).

For the purposes of this invention, an organic photovoltaic cell is a photovoltaic cell in which at least the active layer is made of an organic material.

### BACKGROUND OF THE INVENTION

Photovoltaic modules comprising organic photovoltaic cells represent a real interest in the photovoltaic field. Indeed, the possibility of substituting inorganic semiconductors generally used in photovoltaic cells, such as silicon, copper, indium, gallium, selenium or cadmium telluride, increases the number of systems that can be produced and therefore the possibilities of use. The development of marketable photovoltaic modules comprising several organic photovoltaic cells is currently a major challenge.

In recent years, the development of organic photovoltaic cells has evolved through the use of the inkjet printing technique for their implementation ^{[1],[2]}. Moreover, in 2014, the Applicant developed a process for manufacturing photovoltaic cells using this technique for printing part of the layers of these cells ^{[3]}.

Initially, numerous studies focused on the production of an interfacial layer by inkjet printing of an ink comprising a polymer blend of poly(3,4-ethylenedioxythiophene) and sodium poly(styrene sulfonate), usually referred to by the acronym PEDOT:PSS. Research in this field then focused on inkjet printing of the photovoltaic active layer, which is usually composed of two organic materials, one electron donor and the other an electron acceptor. P₃HT:PCBM is the conventional choice for an organic active layer (P₃HT being the acronym for poly(3-hexylthiophene) and PCBM being the acronym for [6,6]-phenyl-C₇₁-methylbutanoate).

As shown in FIG. 1, in a normally or conventional structured photovoltaic cell 1 currently in use, a first interfacial layer 9, made of PEDOT:PSS for example, is applied to a layer of Indium Tin Oxide (ITO) 3, used as lower electrode, which serves here as anode, and is itself applied to a support. This indium tin oxide layer consists of a metal oxide which, in addition to conducting current, offers the property of being relatively transparent from 350 nm downwards. This is the most commonly used material to collect holes in normally structured organic photovoltaic cells. Above the first interfacial layer 9 is applied a photovoltaic active layer 5 which may, for example, be based on P₃HT:PCBM, and above this photovoltaic active layer 5 is applied a second interfacial layer 6 above which is applied an opaque upper electrode 7 usually made of aluminum, or silver when this layer is applied by inkjet printing, and which serves here as cathode. The two electrodes used in the photovoltaic cell, i.e. the lower electrode and the upper electrode, must have specific properties to enable them to be integrated into organic photovoltaic cells. On the one hand, both electrodes must have high enough conductivities to allow maximum charge collection. On the other hand, the transparency of the lower electrode, generally the indium tin oxide layer, is also a fundamental characteristic for increasing the number of charges photo-generated in the active layer.

Inverted-structure photovoltaic cells are also available today. The main difference with the conventional structure is that the PEDOT:PSS interfacial layer is located between the active layer and the upper electrode, in this case the anode. In this configuration, the indium oxide layer, which is then assimilated to the lower electrode, acts as the cathode and therefore collects electrons. It should be noted that reverse-structure photovoltaic cells have the advantage of being more stable in air than conventionally structured photovoltaic cells, and also generally offer higher conversion efficiencies.

For the purposes of this invention, the conversion efficiency of a photovoltaic cell is defined as the ratio between the maximum electrical power delivered by the cell and the incident light's power, for a given spectral distribution and intensity.

It should be noted, moreover, that the higher conversion efficiencies mentioned above are ensured when photovoltaic modules of the current state of the art are exposed to external radiation, i.e. exposed to ultraviolet (UV), visible, and infrared radiation and can reach light intensities in excess of 5000 lux and in particular to radiation under standard conditions AM1.5, which corresponds to an exposure light intensity with a power of 100 mW/cm², equivalent to a light intensity of around 100,000 lux (corresponding to a power of around 1,000 W/m²). In particular, the high number of photo-generated charges requires the use of an anode with very high electrical conductivity to guarantee good collection of photo-generated charges in the active layer so as to minimize, among other things, the phenomenon of charge accumulation. In particular, the high number of photo-generated charges requires the use of an anode with very high electrical conductivity to guarantee good collection, in the active layer, of photo-generated charges so as to minimize the accumulation phenomenon at the interfacial layers. This is why, in the case of an inverse structure, the upper electrode (or anode) is opaque and made of silver. In this case, conversion efficiencies can reach values of over 15% for organic photovoltaic cells on laboratory-scale.

However, on an industrial scale, due in particular to manufacturing constraints, photovoltaic modules comprising this type of photovoltaic cells have low conversion efficiencies, those being in particular divided by two or more compared with those obtained on a laboratory scale with cells manufactured in a controlled atmosphere (nitrogen-type inert gas). As a result, these photovoltaic modules cannot be used effectively and sustainably under indoor radiation, i.e. at a power of less than 16.2 W/m² when the light intensity is less than 5000 lux, preferably less than 6.4 W/m² when the light intensity is less than 2000 lux, or even less than 3.3 W/m² when the light intensity is less than 1000 lux.

In particular, this low conversion efficiency, when the photovoltaic modules are exposed to indoor radiation, is due in particular to the fact that photovoltaic modules comprising inverse-structure organic photovoltaic cells of the current state of the art have a high series resistance linked to the number of layers forming the organic photovoltaic cell and thus the photovoltaic module. As a result, these photovoltaic modules have inadequate (i.e. not high enough) shunt resistances (or parallel resistances), with shunt resistances continuing to decrease alongside light intensity. As a result, these resistors do not optimize the performance and fill factor of this type of organic photovoltaic module. In particular, it is well known that the shunt resistance needs to be sufficiently high for the photovoltaic module to achieve better output power and fill factor. Indeed, for a low shunt resistance, the current collapses sharply, which means that the power loss is high and the fill factor is low.

Furthermore, the low conversion efficiency of this type of photovoltaic module is also due to the fact that they have high dead surfaces, which are linked to the fact that the deposition of the different constituent layers of each of the organic photovoltaic cells, with an inverse structure in particular, are applied to the substrate in a staggered manner, so that each layer of the organic photovoltaic cell is partly in contact with the support in order to avoid the creation of short circuits that can be caused by the inverse feedback effect of the material deposited in the liquid state, for example. As a result, photovoltaic modules comprising reverse-structured organic photovoltaic cells in the current state of the art have small active areas, which means that they are unable to generate sufficient photo-current when the incident light intensity is low.

In addition, although the indium tin oxide layer used as a cathode has many advantages and interesting electronic properties, it also has certain drawbacks. Indeed, the availability of the materials making up the indium tin oxide layer, the cost of the raw materials, the process associated with its implementation and application to create the layer are all drawbacks to be noted. In addition, the material deposition techniques used to create the indium tin oxide layer involve techniques that are not easily compatible with conventional deposition technologies. The indium tin oxide layer is generally structured to form a continuous film on a rigid or flexible substrate. This film is usually formed by chemical etching (e.g. using acids) or laser ablation. However, these techniques leave effects that can affect the performance of photovoltaic cells, and therefore the photovoltaic modules that comprise them, but also impact the quality and aesthetics of these photovoltaic modules, for example because of visible edge effects. In particular, knowing the cost of indium tin oxide, when film preparation steps are implemented that require the removal of a certain amount of indium tin oxide, the overall process then inevitably becomes costly and creates a certain amount of waste, with all the resulting disadvantages.

In the current state of the art, therefore, there are no organic photovoltaic modules comprising organic photovoltaic cells suitable for indoor radiation as defined above, and which are free from an indium tin oxide layer as anode.

There are currently no photovoltaic modules that can be manufactured entirely by inkjet printing either.

Thus, one of the aims of the invention is to remedy at least in part the shortcomings of photovoltaic modules, and their manufacturing process, of the state of the art.

### SUMMARY OF THE INVENTION

According to a first aspect, the invention relates to a photovoltaic module comprising:
a transparent support,
at least two photovoltaic cells, a first photovoltaic cell and a second photovoltaic cell, on said support, each of said two photovoltaic cells comprising:
   i. a lower electrode consisting of two layers: a first layer comprising a polymer blend of poly(3,4-ethylenedioxythiophene) and sodium poly(styrene-sulfonate) covering the support and having an average thickness of between 50 nm and 150 nm and an organic fibrous structure, and a second layer based on an organic polymer or molecule covering said first layer, the lower electrode having a lower surface in contact with the support and an upper surface,
   ii. a photovoltaic active layer covering said upper surface of said lower electrode;
   iii. an upper electrode comprising a polymer blend of poly(3,4-ethylenedioxythiophene) and sodium poly(styrene-sulfonate) covering said photovoltaic active layer, said electrode being continuous, having an average thickness of between 100 nm and 400 nm and an organic fibrous structure,
   the upper electrode of the first photovoltaic cell being in contact with said second layer of said lower electrode of the second photovoltaic cell.

According to this first aspect, the invention makes it possible to avoid the disadvantages inherent in the use of a tin oxide electrode, such as those mentioned above, in particular those linked to the complexity of deposition, etching or cleaning, while providing a photovoltaic module that can be used under indoor radiation.

Furthermore, the indium tin oxide layer generally used as cathode in photovoltaic modules comprising reverse-structure photovoltaic cells of the prior art cannot be used without the presence of a first interfacial layer between it and the active layer. Indeed, the presence of the first interfacial layer is currently necessary in the cells to facilitate the transfer of charges between each of the layers, this being due in particular to the work output of the indium tin oxide layer, which is high, in particular approximately equal to 4.7 eV.

The invention then has the advantage of overcoming this problem by providing a lower electrode made up of two layers. The second layer, based on an organic polymer or molecule, reduces the energy barrier between the active layer and the first layer of the lower electrode, by lowering the latter's work output. Rather than a Schottky contact, the final result is an ohmic contact that is favorable to charge collection, particularly electron collection. In particular, according to the invention, adsorption of the polymer or organic molecule, due to the transfer of charges, in particular protons, from the hydroxyl groups to the amino groups, generates a dipole opposite to Δ\vec{Ø} (Δ\vec{Ø} being a surface dipole), leading to a reduction of Δ\vec{Ø}, this reduces the work output of the lower electrode.

In addition, the second layer of the lower electrode also acts as a barrier to block positive charges passing through, leading to a further increase in photovoltaic module performance as a result of reduced leakage currents.

The invention according to this first aspect also makes it possible to have a photovoltaic module which is free of an indium tin oxide layer used as a lower electrode, this layer being generally used in photovoltaic modules of the prior art. In particular, the lower electrode here consists of two layers, so it can be referred to as a bilayer lower electrode. Each of the layers making up the lower electrode is organic.

Other transparent substrates include polyethylene terephthalate (commonly known by the acronym PET), polyethylene naphthalate (commonly known by the acronym PEN) and glass.

Having a bilayer enables the photovoltaic module to function as it is necessary for the work output of the lower electrode to be different from that of the upper electrode.

In particular, the use of a second layer based on an organic polymer or molecule enables the lower electrode to be structurally differentiated from the upper electrode. Also, the presence of this second layer based on an organic polymer or molecule enables the bilayer lower electrode to act both as a first interfacial layer (or electron transfer layer), and also as a work output modifier for the polymer blend of poly(3,4-ethylenedioxythiophene) and sodium poly(styrene sulfonate).

Preferably, the material constituting the first layer of the lower electrode can be the same as that constituting the upper electrode. In this way, it is possible to avoid the need to develop an inkjet printable formulation dedicated solely to the formation of this first layer of the lower electrode. This also avoids the disadvantages, particularly ecological and economical, associated with the use of an additional formulation. Furthermore, the materials used to manufacture the upper electrode, and therefore possibly the first layer of the lower electrode, are present in abundance and made up of organic materials.

Preferably, the lower electrode can be sufficiently transparent to allow photons to pass from the support to the active layer, so as to collect as much of the photo-generated charge as possible.

In a particular embodiment, the thickness of the second layer of the lower electrode may be between 2 and 5 nm and may comprise amine groups on its lower surface in contact with the upper surface of the first layer of the lower electrode.

In a particular embodiment, the second layer of the lower electrode can be continuous, transparent and free of metal oxide. In this way, a non-toxic second layer of the lower electrode can be obtained.

In a particular embodiment, the upper electrode can have a square surface resistance between 50Ω/□ and 300Ω/□. This square resistance is obtained by manufacturing a layer using inkjet printing.

In a particular embodiment, the upper electrode can have a Root Mean Square (RMS) roughness equal to or less than 5 nm.

In a particular embodiment, the second layer of the lower electrode can have an RMS roughness equal to or less than 5 nm.

In a particular embodiment, the second layer of the lower electrode may comprise nitrogen.

In a particular embodiment, the layers making up the module (apart from the support) are all organic, so as to obtain a module that is environmentally friendly. Consequently, the photovoltaic module can be organic, in the sense that the module comprises only organic printed layers.

In a particular embodiment, the organic polymer or molecule can be selected from Poly(9,9-bis(3′-(N,N-dimethyl)-N-ethylammonium-propyl-2,7-fluorene)-alt-2,7-(9,9-dioctylfluorene))dibromide (PFN-Br), polyethyleneimine (PEI), ethoxylated polyethyleneimine (PEIE), Poly [(9,9-bis(3′-(N,N-dimethylamino)propyl)-2,7-fluorene)-alt-2,7-(9,9-dioctylfluorene)](PFN), N,N′-Bis(N,N-dimethylpropan-1-amine oxide)perylene-3,4,9,10-tetracarboxylic diimide (PDI-NO) or N,N′-Bis{3-[3-(Dimethylamino)propylamino]propyl}perylene-3,4,9,10-tetracarboxylic diimide (PDINN).

According to a second aspect, the invention relates to a process for manufacturing a photovoltaic module as hereinbefore defined, comprising the following steps:
a) providing a transparent support;
b) realization on said support two layers of a first layer of the lower electrode comprising a polymer blend of poly(3,4-ethylenedioxythiophene) and sodium poly(styrene-sulfonate),
c) realization on each of the two layers of a first layer of the lower electrode and a second layer of the lower electrode based on an organic polymer or molecule,
d) realization on each of the two layers of a second layer of the lower electrode of a photovoltaic active layer;
e) realization an upper electrode on said photovoltaic active layer;
said process being characterized in that steps b), c), d) and e) are each carried out by depositing ink compositions by digital inkjet printing, followed by heat treatment.

According to this second aspect, the invention makes it possible to manufacture a photovoltaic module comprising a bilayer lower electrode made from two different ink compositions by digital inkjet printing. These two compositions are both preferably based on non-toxic solvents known to the skilled person and on organic materials, so as to enable them to be deposited in ambient air by digital inkjet printing. As a result, steps b) and c) for producing the first and second layers of the lower electrode, respectively, are easy to implement, as these steps dispense with the structuring step for the indium tin oxide layer currently used in the state of the art.

In addition, the fact that all the process steps are carried out by depositing ink compositions using digital inkjet printing reduces the manufacturing costs of the photovoltaic module.

Indeed, the chemical etching step generally implemented for structuring the lower electrode, which comprises indium tin oxide for example, in prior art photovoltaic modules requires several costly sub-steps, notably due to the etching implementation times, the costs inherent to the use of a cross-linkable resin and the use of deposition equipment. In particular, this chemical etching step generally consists of at least several sub-steps: a mask application step, an actual etching step (using, for example, one or more acid baths) and a cleaning step to remove the remaining part of the mask.

In a particular embodiment, it is advantageous not to alter the substrate during the annealing treatment in step b). Consequently, the heat treatment in step b) can be an annealing treatment carried out at a temperature between 100° C. and 160° C., for a duration between 1 and 5 minutes.

In a particular embodiment, it is advantageous not to alter the substrate and layers previously produced in step c). Consequently, the heat treatment in step c) can be an annealing treatment carried out at a temperature between 100° C. and 160° C., for a duration between 1 and 5 minutes.

In a particular embodiment, the wettability of the composition from which the first layer of the lower electrode is derived can preferably be compatible with flexible substrates of, for example, polyethylene terephthalate, to facilitate the formation of a continuous film with well-defined edges by digital inkjet printing.

Preferably, during step b) of making the two layers of a second layer of the lower electrode, the composition below can be applied by digital inkjet printing to the support, said composition having a viscosity of between 2 and 50 mPa·s at 20° C. and comprising:
between 0.1% and 0.5% by weight of at least one polymer or organic molecule relative to the total weight of said ink composition, the polymer or organic molecule comprising amine groups and being soluble in polar solvents,
between 2% and 10% by weight of additives relative to the total weight of said ink composition,
between 80% and 90% by weight of one or more polar solvents relative to the total weight of said ink composition, and
between 1% and 5% by weight of water relative to the total weight of said ink composition.

The polymer or organic molecule has the advantage of not being sensitive to UV radiation, this being due to its intrinsic characteristics which are different from those of metal oxide nanoparticles usually used in the layers of the lower electrode of photovoltaic modules in the prior art. In particular, the metal oxides classically used in the prior art in interfacial layers, such as TiO₂ or ZnO, are not very effective under solar irradiation due to their high gap energy, which means they can only be activated by UV radiation. This activation allows charges (electrons) to flow through the interfacial layer to reach the electrode without being trapped. However, the requirement for UV exposure can impose major problems if photovoltaic modules are intended for indoor applications where artificial lighting sources are used, generally LEDs which do not emit in the UV range.

The additives are used to solubilize the polymer or organic molecule to obtain a composition that is, on the one hand, defined by a high evaporation temperature to prevent the nozzles of a digital inkjet printing application device from clogging, and on the other hand, to improve the viscosity of the ink composition.

The polar solvents are preferably non-toxic in order to guarantee deposition of the ink composition in ambient air with the nozzles of an industrial digital inkjet printing application device.

Preferably, the polymer or organic molecule can be selected from Poly(9,9-bis(3′-(N,N-dimethyl)-N-ethylammonium-propyl-2,7-fluorene)-alt-2,7-(9,9-dioctylfluorene))dibromide (PFN-Br), polyethyleneimine (PEI), ethoxylated polyethyleneimine (PEIE), Poly [(9,9-bis(3′-(N,N-dimethylamino)propyl)-2,7-fluorene)-alt-2,7-(9,9-dioctylfluorene)](PFN), N,N′-Bis(N,N-dimethylpropan-1-amine oxide)perylene-3,4,9,10-tetracarboxylic diimide (PDI-NO) or N,N′-Bis{3-[3-(Dimethylamino)propylamino]propyl}perylene-3,4,9,10-tetracarboxylic diimide (PDINN).

Preferably, said one or more solvents can be selected from ethanol, isopropanol, hexanol, terpiniol, ethylene glycol, deionized water, phosphate saline buffer solution, butanol, di-ethylene glycol, glycerol.

In a particular embodiment, the polymer or organic molecule may comprise nitrogen.

Further advantages and features of the present invention will become apparent from the following description, made with reference to the appended figures and the following examples:

### BRIEF DESCRIPTION OF FIGURES

FIG. 1 shows a schematic cross-section of a photovoltaic cell with a conventional structure;

FIG. 2 shows a schematic cross-sectional view of a photovoltaic module comprising photovoltaic cells according to a particular mode of the invention;

FIG. 3 shows the characteristic spectrum of the Philips 60×60 cm² LED panel used in the examples,

FIG. 4 shows the transmission spectra of the ITO electrode used to produce modules M2A and M2B according to the prior art, and of the bilayers used to produce modules M1A and M1B according to the invention, with the wavelength (A) on the x-axis and the transmission (T) on the y-axis.

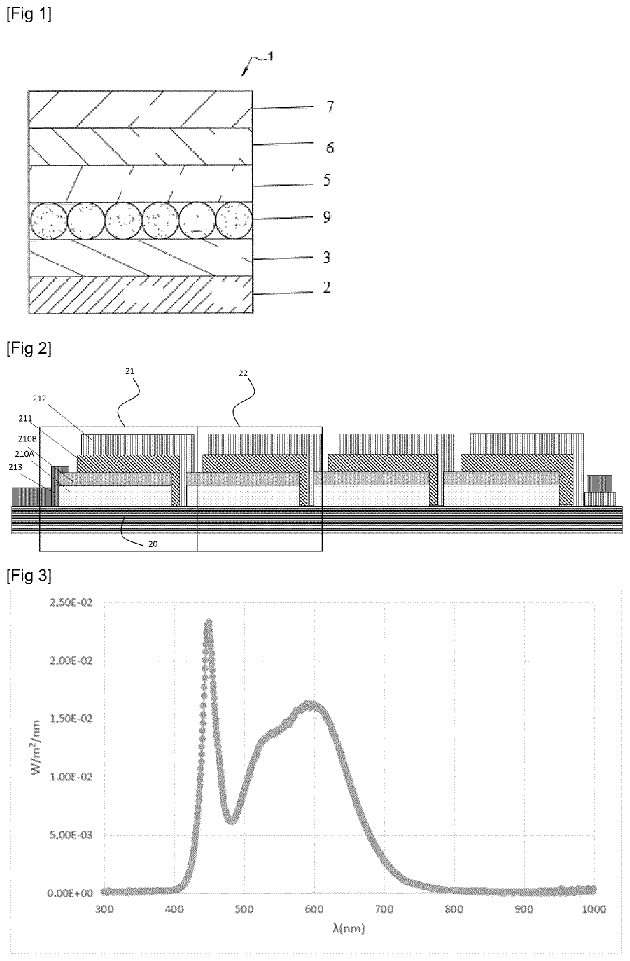

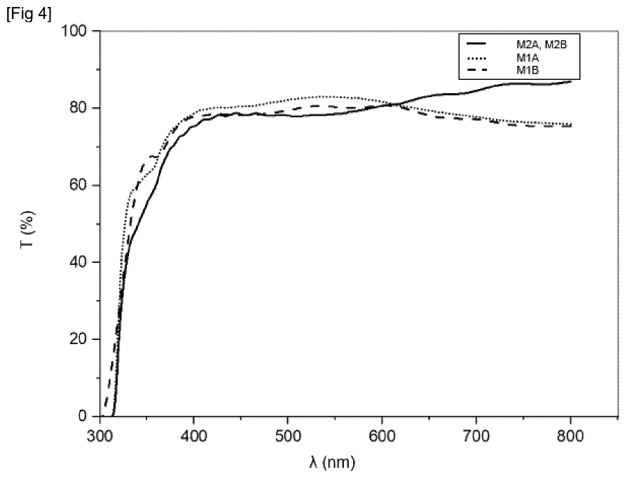

FIG. 1 is described in the preceding overview of the prior art, while FIG. 2 is described in greater detail in the following examples, which illustrate the invention without limiting its scope.

### EXAMPLES

### Products

support 20 in PET or glass;
cleaning solvents:
   in the case of rigid glass supports: deionized water, Acetone, Ethanol, Isopropanol, and
   in the case of flexible substrates, as these are protected by plastic films, they do not require cleaning as in the case of rigid substrates.
a first ink composition E11 for producing a discontinuous first layer 210A comprising a polymer blend of poly(3,4-ethylenedioxythiophene) and sodium poly(styrene sulfonate) so that the substrate is partially covered with a first layer 210A of a bilayer lower electrode 210 of the photovoltaic cells 21 and 22 of the photovoltaic module of FIG. 2
ink E11 comprising:
PEDOT:PSS marketed by Agfa® under the trade name IJ1005, and
Triton X-100 (4-(1,1,3,3-tetramethylbutyl)phenyl-polyethylene glycol of the formula Oct-C₆H₄—(OCH₂CH₂)ₓOH, x=9-10) marketed by Merck® as detergent/surfactant.

a second ink composition (E12A and E12B) for producing a second layer 210B based on an organic polymer or molecule so that the first layer 210A of the bilayer lower electrode 210 is partially covered by a second layer 210B of a bilayer lower electrode 210 to form the cathodes of the various organic photovoltaic cells 21 and 22 of the photovoltaic module of FIG. 2 hereinafter described:
E12A ink comprising:
a first Solvent 1: Butanol at a mass concentration approximately equal to 91.094% relative to the total weight of E12A ink,
a second Solvent 2: deionized water at a concentration by weight approximately equal to 3.124% relative to the total weight of the E12A ink,
an additive: Ethylene glycol at a concentration by weight of approximately 5.563% relative to the total weight of E12A ink,
a PEI at a concentration by weight of approximately 0.219% based on the total weight of E12A ink.
   The solvents, additives and PEI are marketed by Merck®.
E12B ink comprising:
9 mL Butanol,
500 μL Ethylene glycol,
100 μL aqueous commercial solution of PEIE (at a mass concentration approximately equal to 37% in water).
   The solvents, additives and PEIE are marketed by Merck®.

a third ink composition E20 for producing the photovoltaic active layers 211 of the photovoltaic cells 21 and 22 of the photovoltaic module of FIG. 2:
polymer blend of an acceptor fullerene derivative comprising:
PC60BM: [60]PCBM, 3′H-cyclopropa[1,9][5,6]fullerene-C60-Ih-3′-butanoic acid 3′-phenyl methyl ester marketed by Special Carbon Products, and
a semiconductor donor polymer marketed by Raynergy Tek® under the trade name PV2000);
O-xylene as solvent (ortho-xylene of formula C₆H₄(CH₃)₂); and
Tetralin (1,2,3,4-tetrahydronaphthaline) as an additive.
   The PV2000 polymer is present in these third ink compositions at 15 mg/ml.
   The weight ratio of PV2000 polymer to PC60BM is 1:1.5.
   The volume ratio between O-xylene solvent and Tetralin additive is 50:50 in these second compositions.
   The third E20 ink composition is kept for 24 hours under agitation on a hot plate at 80° C. at a speed of 700 RPM.
a fourth ink composition E30 for producing the upper electrodes 212 (or anode) of the photovoltaic cells 21 and 22 of the photovoltaic module shown in FIG. 2:
PEDOT:PSS marketed by Agfa® under the trade name IJ1005,
Triton X-100 (4-(1,1,3,3-tetramethylbutyl)phenyl-polyethylene glycol of the formula Oct-C₆H₄—(OCH₂CH₂)ₓOH, x=9-10) marketed by Merck® as detergent/surfactant;

### Tests

### RMS Roughness Measurement

These measurements are carried out using an atomic force microscope (Nanoscope III Multimode SPM from Brucker®, used in intermittent contact mode (or “tapping mode”), with hq:nsc15 tips marketed by MiKromasch® and having a curvature radius of 8 nm), the measurements were carried out on various samples of photovoltaic cells according to the invention and according to the prior art.

### Measuring Layers Thicknesses

The thickness of printed layers is measured using a DektakXT tip profilometer marketed by BRUKER, based on a scratch made with a cutter blade (thus creating a channel with the thickness of the deposit). This is a contact profilometer that measures variations in relief by vertically moving a pointed stylus across the surface, applying a constant contact force and revealing any unevenness. The sample is placed on a plate which allows it to move at a given speed over a chosen distance. The thickness values presented in this patent application correspond to the average of five measurements taken at six different points on the same step of a sample. Before measurements are taken, the length of the zone scanned, its duration, the force with which the stylus is pressed and the measurement range must be defined.

### Electrical Resistivity Measurement

This measurement is carried out using the 4-tips technique, as follows:
the 4 tips are aligned far from the edges of the layer to be characterized;
these 4 tips are equidistant from each other; and
current is generated by a current generator between the outer tips, while voltage is measured between the inner tips. The ratio of the measured voltage to the current flowing through the sample gives the resistance of the section between the inner tips.

### Viscosity Measurement:

The viscosity of a fluid is reflected in its resistance to deformation or relative sliding of its layers. During the flow of a viscous fluid in a capillary tube, for example, the velocity of the molecules (v) is at its highest in the axis of the tube, decreasing until it reaches zero at the wall, while relative sliding occurs between the layers, giving rise to tangential frictional forces. In fluids, tangential forces depend on the nature of the fluid and its flow regime.

The Ubbelhode viscometer is placed in a thermostat maintained at a constant temperature (25° C. in our case). We measure the flow time of a constant volume V defined by two reference marks (M1 and M2) located on either side of a small reservoir surmounting the capillary.

### Photovoltaic Performance Measurement Indoors:

A characterization bench is used indoors to study the ageing of modules produced under permanent lighting. The characterization bench comprises an opaque enclosure (to avoid any light coming from the outside) equipped with a LED lighting source (in particular a Keithley 2450 source-meter) and a computer with a LabVIEW program for automatic measurement of module performance (determination of photovoltaic parameters) at a well-defined frequency (e.g. 10 times a day). The photovoltaic modules are permanently illuminated by a lighting source with a light intensity of around 1000 lux measured by a luxmeter (in particular the Chauvin Arnoux Ca 1110 luxmeter) compatible with a wide variety of light sources, including LED and fluorescent light up to 200,000 lux, in compliance with class C of standard NF C 42-710.

The lighting source used for indoor and performance measurements is a Philips LED panel 60×60 cm2—4385K with an emission spectrum in the visible range (see spectrum shown in FIG. 3).

### Morphology Characterization:

AFM (Atomic Force Microscope) measurements to reproduce surface topography and TEM (Transmission Electron Microscopy) to validate the crystalline nature of the materials and the size of nanoparticles present in the layers.

### Measuring Bilayer Transmission:

In order to determine the transmission spectra of the bilayers printed according to the invention (see the spectrum shown in FIG. 3). A Cary 5000 UV-Vis-NIR UV-Visible spectrometer was used. This method is based on the use of equipment that determines the transmission of a thin layer for a given wavelength or for a judiciously chosen range of wavelengths. The sample is placed on a sample holder and irradiated with monochromatic radiation. A computer compares the intensity (I) of the test sample (PET substrate and deposited layer) with that of the reference sample (PET substrate alone) (10). By scanning several wavelengths in the 300-800 nm range (in our case), it displays the transmission spectrum of the bilayer. On the ordinate, this spectrum shows the transmission T (%) as a function of wavelength (nm).

EXAMPLE 1: obtaining examples of the first ink composition E10 for producing the first layer 210A of the bilayer lower electrode.

This first E10 ink composition for producing the first layer of the lower electrode is obtained as follows:
the PEDOT:PSS solution (IJ1005) initially stored in a refrigerator is filtered through a 0.45 μm filter,
30 μl of Triton X-100 is mixed with 10 ml of the filtered PEDOT:PSS solution,
The resulting mixture is stirred on a magnetic stirrer at room temperature for 16 hours.
the final E10 solution is degassed for 3 to 5 minutes in an ultrasonic bath before printing.

EXAMPLE 2: obtaining an example of a second ink composition E12A and E12B for producing the second layer 210B of the lower electrode 210.

Depending on whether PEI or PEIE is used, E12A and E12B ink compositions are obtained respectively, the compositions of which are detailed below:

The E12A ink formulation is prepared in two stages:

### Step 1: Preparation of the Stock Solution:

Weigh 0.35 g PEI (interlayer polymer)
Add 5 ml of ionized water to these 0.35 g of PEI
Stir at 60° C. for at least 4 h to obtain the stock solution.

### Step 2: Preparation of E12A Ink Formulation:

Take 250 μL of the stock solution,
Add 9 ml Butanol,
Add 400 μL ethylene glycol,
Stir the mixture at room temperature for 24 hours to obtain the E12A formulation.
The E12A formulation is filtered before printing, using an AC filter with a cut-off of around 0.2 μm.

The E12B ink formulation is prepared in a single step:

### Preparation of E12B Ink Formulation:

Take a 100 μL volume of the commercial aqueous solution of PEIE
Add 9 ml Butanol (solvent)
Add 500 μL ethylene Glycol (additive)
Stir the mixture at room temperature for 24 hours to obtain the E12B ink formulation. The E12B formulation is filtered before printing, using an AC filter with a cut-off of around 0.2 μm.

EXAMPLE 3: Obtaining an example of a third ink composition E20 for producing photovoltaic active layer 211.

PC60BM is used as acceptor in combination with PV2000 as donor to obtain the E20 ink composition detailed in Table 1 below:

TABLE 1

| Composition | E21 | |
|---|---|---|
| PC60BM | 22.5 | mg |
| PV2000 | 15 | mg |
| O-xylene | 1 | mL |
| Tetralin | 1 | mL |

The E20 ink composition is obtained as follows:
15 mg PV2000 mixed with 22.5 mg PC60BM (corresponding to a weight ratio of 1:1.5) in 0.5 ml o-xylene and 0.5 ml tetralin.
The mixture is placed under magnetic stirring on a hot plate at 80° C. for 24 hours.
Before printing, the ink is filtered using an AC filter with a cut-off of around 0.45 micrometers.

EXAMPLE 4: Obtaining an example of a fourth ink composition E30 for producing the upper electrode layer 212.

An example of a fourth E30 ink composition is obtained for the upper electrode layer 212.

This fourth ink composition E30 for producing the upper electrode layer 212 is obtained as follows:
the PEDOT:PSS solution (IJ1005) initially stored in a refrigerator is filtered with a filter having a cut-off of approximately 0.45 μm,
30 μl of Triton X-100 is mixed with 10 ml of the filtered PEDOT:PSS solution,
the resulting mixture is stirred on a magnetic stirrer at room temperature for 16 hours, and
the final E30 solution is degassed for 3 to 5 minutes in an ultrasonic bath before printing.

EXAMPLE 5: Obtaining examples of photovoltaic modules according to the invention:

Two photovoltaic modules M1A and M1 B according to the invention are produced by the following process:
Supply of a transparent PET or glass support.
Production on said support of two layers of a first layer 210A of lower electrode 210 from the composition E10 of example 1. In particular, these layers are produced by digital inkjet printing of the E10 ink composition, followed by thermal annealing in a convection oven at 145° C. for 3 minutes. The thickness of the first printed layers 210A of lower electrodes 210 is around 100 nm, with RMS roughness of less than 5 nm.
On each of the two layers, a first layer 210A of lower electrode 210 and a second layer 210B of lower electrode 210 are produced using either the ink composition E12A of example 2 (photovoltaic module M1A) or the ink composition E12B of example 2 (photovoltaic module M11B). In particular, these layers are produced by digital inkjet printing with either ink composition E12A or E12B, followed by thermal annealing in a convection oven at 145° C. for 3 minutes.
   The thickness of the printed second layers 210B of lower electrode 210 is between 2 and 5 nm, with RMS roughness of less than 2 nm.
A photovoltaic active layer 211 is applied to each of the two layers of a second layer 210B of lower electrode 210 by digital inkjet printing with ink composition E20 from example 3, followed by thermal annealing in a convection oven at 145° C. for 3 minutes. The thickness of the printed 211 photovoltaic active layers is around 350 nm, with RMS roughness of less than 5 nm.
A upper electrode 212 is applied to each of the photovoltaic active layers 211 by digital inkjet printing with ink composition E30 from example 4, followed by thermal annealing in a convection oven at 145° C. for 3 minutes. The thickness of the printed upper electrode layers 212 is approximately 500 nm, with RMS roughness of less than 10 nm.
Production of an electrical contact layer 213 consisting of a copper tape with adhesive, 3 mm wide and 58 mm long. This tape is marketed by “3M” and cut into strips (3*58 mm2) using a mechanical cutting machine (Kongsberg XE). This electrical contact layer 213 is then deposited so as to ensure contact between the upper electrode layer 212 of a first photovoltaic cell of the photovoltaic module (M1A or M1B) and the second layer of the lower electrode 210B of a second photovoltaic cell of the photovoltaic module (M1A or M1B).

At the end of the manufacturing process, a photovoltaic module (either M1A or M1B) is obtained, comprising organic photovoltaic cells 21 and 22, which then comprise, among other things, a bilayer lower electrode according to embodiments of the invention, and an upper electrode featuring a micrometric organic fibrous structure.

RESULTS AND COMPARISONS: Characterization of photovoltaic modules obtained in previous examples M1A and M1B and comparisons with examples of photovoltaic modules in the prior art.

The various photovoltaic modules, according to the invention and prior art, have been characterized according to the tests indicated above and the results of these characterizations in Table 2 below.

Two photovoltaic modules (M2A and M2B) according to the prior art have been produced under the same conditions as those used to produce photovoltaic modules M1A and M1B according to examples of the invention.

The first photovoltaic module M2A according to the prior art differs from the photovoltaic modules M1A and M1B according to the invention by the presence of a lower electrode comprising an indium tin oxide layer and an interfacial layer based on metal oxides, in particular AZO (Aluminum-doped Zinc Oxyde) and the second photovoltaic module M2B according to the prior art differs from the photovoltaic modules M1A and M1B according to the invention by the presence of a lower electrode comprising an indium tin oxide layer and an interfacial layer based on metal oxides, in particular SnO₂ (tin dioxide). AZO is marketed by Genesink and SnO2 is marketed by Avantama.

The photovoltaic modules M2A and M2B according to the prior art were produced in reverse structure with the active layer PV2000:PC60BM and PEDOT:PSS as upper electrode, i.e. with the same active layers and upper electrodes as the examples according to the invention.

The photovoltaic modules M1A, M1B according to the invention and M2A, M2B according to the prior art were characterized under the same conditions with the same characterization bench described above under the same light intensity.

Repeated production of photovoltaic modules corresponding to the M1A module has produced the results shown in Table 2 below under the reference M1A′.

TABLE 2

| | Light | | | | Filling |
|---|---|---|---|---|---|
| Photovoltaic | intensity | Voc | Isc | Pmax | factor |
| modules | in lux | (in V) | (in μA) | (in μW) | (%) |
| M1A | 1000 | 3.84 ± 0.02 | 305 ± 5 | 726 ± 5 | 62 ± 2 |
| M1A′ | 1000 | 3.85 ± 0.02 | 327 ± 5 | 792 ± 5 | 64 ± 2 |
| M1B | 1000 | 3.42 ± 0.02 | 280 ± 4 | 574 ± 3 | 60 ± 3 |
| M2A | 1000 | 3.92 ± 0.04 | 266 ± 8 | 683 ± 1 | 66 ± 2 |
| M2B | 1000 | 3.80 ± 0.02 | 336 ± 4 | 845 ± 11 | 66 ± 1 |

The above table shows the photovoltaic parameters (voltage, current, maximum power and fill factor) measured under LED-type indoor lighting (1000 LUX), and clearly shows that the photovoltaic modules M1A and M1B according to the invention achieve photovoltaic performances very close to, and sometimes better than, those of modules produced according to the state of the art under the same conditions (same active layer and same upper electrode). The current generated by modules according to the invention is of the same order of magnitude as that generated by modules made according to the prior art.

The photovoltaic performances measured with the M1A and M1B photovoltaic modules according to the invention are very encouraging and confirm the good functionality of the bilayer lower electrode according to the invention in the case of an indoor application (low-light LED-type lighting).

### REFERENCES

[1] Sharaf Sumaiya, Kamran Kardel, and Adel EI-Shahat. “Organic Solar Cell by Inkjet Printing—An Overview.” 53, Georgia, USA: Technologies, 2017, Vol. 5.
[2] Peng, X., Yuan, J., Shen, S., Gao, M., Chesman, A. S. R., & Yin, H. (2017). “Perovskite and Organic Solar Cells Fabricated by Inkjet Printing: Progress and Prospects,” Adv. Funct. Mater. 2017, 1703704
[3] European patent application EP2960957 by DRACULA TECHNOLOGIES, filed on Jun. 25, 2015 and published on Dec. 30, 2015.

1. Photovoltaic module comprising:
a transparent support,
at least two photovoltaic cells, a first photovoltaic cell and a second photovoltaic cell, on said support, each of said two photovoltaic cells comprising:
i. a lower electrode consisting of two layers: a first layer comprising a polymer blend of poly(3,4-ethylenedioxythiophene) and sodium poly(styrene-sulfonate) covering the support and having an average thickness of between 50 nm and 150 nm and an organic fibrous structure, and a second layer based on an organic polymer or molecule covering said first layer, the lower electrode having a lower surface in contact with the support and an upper surface,
ii. a photovoltaic active layer covering said upper surface of said lower electrode,
iii. an upper electrode comprising a polymer blend of poly(3,4-ethylenedioxythiophene) and sodium poly(styrene sulfonate) covering said photovoltaic active layer, said electrode being continuous, having an average thickness of between 100 nm and 400 nm and an organic fibrous structure,
the upper electrode of the first photovoltaic cell being in contact with said second layer of said lower electrode of the second photovoltaic cell.

2. Photovoltaic module according to claim 1, according to which the thickness of said second layer of said lower electrode is between 2 and 5 nm and comprises amine groups on its lower surface in contact with the upper surface of the first layer of said lower electrode.

3. Photovoltaic module according to claim 1, wherein said second layer of said lower electrode is continuous, transparent and free of metal oxide.

4. Photovoltaic module according to claim 1, wherein said upper electrode has a square resistance between 50Ω/□ and 300 Ω/□.

5. Photovoltaic module according to claim 1, wherein said upper electrode has an RMS roughness equal to or less than 5 nm.

6. Photovoltaic module according to claim 1, wherein said second layer of said lower electrode has an RMS roughness equal to or less than 5 nm.

7. Photovoltaic module according to claim 1, wherein said second layer of said lower electrode comprises nitrogen.

8. Photovoltaic module according to claim 1, characterized in that it is organic.

9. Photovoltaic module according to claim 1, wherein the polymer or organic molecule is selected from Poly(9,9-bis(3′-(N,N-dimethyl)-N-ethylammonium-propyl-2,7-fluorene)-alt-2,7-(9,9-dioctylfluorene))dibromide (PFN-Br), polyethyleneimine (PEI), ethoxylated polyethyleneimine (PEIE), Poly [(9,9-bis(3′-(N,N-dimethylamino)propyl)-2,7-fluorene)-alt-2,7-(9,9-dioctylfluorene)](PFN), N,N′-Bis(N,N-dimethylpropan-1-amine oxide)perylene-3,4,9,10-tetracarboxylic diimide (PDI-NO) or N,N′-Bis{3-[3-(Dimethylamino)propylamino]propyl}perylene-3,4,9,10-tetracarboxylic diimide (PDINN).

10. A method of manufacturing a photovoltaic module as defined according to claim 1, comprising the following steps:
a) provision of a transparent support;
b) realization on said support of two layers of a first layer of the lower electrode comprising a polymer blend of poly(3,4-ethylenedioxythiophene) and sodium poly(styrene-sulfonate);
c) realization on each of the two layers of a first layer of the lower electrode of a second layer of the lower electrode based on a polymer or organic molecule;
d) realization on each of the two layers of a second layer of the lower electrode of a photovoltaic active layer;
e) realization of an upper electrode on said photovoltaic active layer, said process being characterized in that steps b), c), d), and e) are each performed by depositing ink compositions by digital inkjet printing, followed by heat treatment.

11. Manufacturing process according to claim 10, wherein the heat treatment in step b) is an annealing treatment carried out at a temperature between 100° C. and 160° C., for a duration between 1 and 5 minutes.

12. Manufacturing process according to claim 10, wherein the heat treatment in step c) is an annealing treatment carried out at a temperature between 100° C. and 160° C., for a duration between 1 and 5 minutes.

13. Manufacturing process according to claim 10, according to which during step b) of making the two layers of a second layer of the lower electrode, the composition below is applied by digital inkjet printing on the support, said composition having a viscosity of between 2 and 50 mPa·s at 20° C. and comprising:
between 0.1% and 0.5% by weight of at least one polymer or organic molecule relative to the total weight of said ink composition, the polymer or organic molecule comprising amine groups and being soluble in polar solvents,
between 2% and 10% by weight of additives relative to the total weight of said ink composition,
between 80% and 90% by weight of one or more polar solvents relative to the total weight of said ink composition, and
between 1% and 5% by weight of water relative to the total weight of said ink composition.

14. Process according to claim 13, wherein the polymer or organic molecule is selected from Poly(9,9-bis(3′-(N,N-dimethyl)-N-ethylammonium-propyl-2,7-fluorene)-alt-2,7-(9,9-dioctylfluorene))dibromide (PFN-Br), polyethyleneimine (PEI), ethoxylated polyethyleneimine (PEIE), Poly [(9,9-bis(3′-(N,N-dimethylamino)propyl)-2,7-fluorene)-alt-2,7-(9,9-dioctylfluorene)](PFN), N,N′-Bis(N,N-dimethylpropan-1-amine oxide)perylene-3,4,9,10-tetracarboxylic diimide (PDI-NO) or N,N′-Bis{3-[3-(Dimethylamino)propylamino]propyl}perylene-3,4,9,10-tetracarboxylic diimide (PDINN).

15. Process according to claim 13, wherein said one or more solvents are selected from ethanol, isopropanol, hexanole, terpiniol, ethylene glycol, deionized water, phosphate salt buffer solution, butanol, di-ethylene glycol, glycerol.

16. Process according to claim 13, wherein the polymer or organic molecule comprises nitrogen.
